(19) United States
(12) Patent Application Publication
(10) Pub. No.: US 2002/0171140 A1
(43) Pub. Date: Nov. 21, 2002

(54) Tape carrier package (TCP) on which semiconductor chips are mounted and method of manufacuturing the same

(75) Inventor: Bum-Yeul Park, Seoul (KR)

Correspondence Address: Steven M. Mills, MILLS & ONELLO LLP, Suite 605, Eleven Beacon Street, Boston, MA, 02108, US

(73) Assignee: Samsung Electronics Co. Ltd.

(21) Appl. No.: 10/047,272

(22) Filed: Jan. 14, 2002

(30) Foreign Application Priority Data
May 18, 2001 (KR) 01-27326

(51) Int. Cl. H05K 7/06; H01L 23/12

(52) U.S. Cl. 257/723; 361/749; 174/254; 174/268; 257/701

(57) ABSTRACT

A package for mounting a plurality of semiconductor chips on one package and minimizing a mounted area, and a method of manufacturing the same is provided. The package includes a film on which a plurality of semiconductor chips are mounted, and the film is folded in a predetermined direction so as to package the plurality of semiconductor chips in one package. The method of manufacturing the package includes mounting a plurality of semiconductor chips on a film and folding the film in a predetermined direction and packaging the plurality of semiconductor chips in one package. The film is folded two or more times such that at least one semiconductor chip is interposed between surfaces of the film. The package can be a tape carrier package (TCP) or a chip-on-film (COF) package.

### BACKGROUND OF THE INVENTION

1. Field of the Invention

The present invention relates to a semiconductor memory device, and more particularly, to a tape carrier package (TCP) which is capable of packaging a plurality of semiconductor chips in one package.

2. Description of the Related Art

A tape carrier package (TCP) or a chip-on-film (COF) package is an optimum package shape for packaging a multi-pinned semiconductor memory device in small sized units and is widely used in packaging a liquid crystal display driving integrated chip (LDI).

FIG. 1 is a sectional view of a conventional tape carrier package (TCP). Referring to FIG. 1, the TCP includes a semiconductor chip 7, an insulating film 1 (or base film) having a device hole 4, a conductive pattern 3 formed on the insulating film 1, a bump 2 for electrically connecting an electrode (not shown) of the semiconductor chip 7 to the conductive pattern 3, a solder resist 5 for protecting the conductive pattern 3, and a sealing resin 9 for sealing the semiconductor chip 7 and the insulating film 1.

The conventional TCP packages one semiconductor chip, and thus, it is difficult to reduce the size of a package in a semiconductor memory device requiring a plurality of semiconductor chips.

### SUMMARY OF THE INVENTION

To solve the above problems, it is a first object of the present invention to provide a package which is capable of packaging a plurality of semiconductor chips in one package and minimizing the size of the package.

It is a second object of the present invention to provide a method of manufacturing a package.

Accordingly, to achieve the first object, there is provided a packaging structure for packaging a plurality of semiconductor chips. The packaging structure includes a film on which the plurality of semiconductor chips are mounted, and the film is folded in a predetermined direction so as to package the plurality of semiconductor chips in one package.

In one embodiment, the film includes an insulating film and a conductive pattern formed on the surface of the insulating film and is folded two or more times such that at least one semiconductor chip is interposed between surfaces of the film.

The package can be a tape carrier package (TCP) or a chip-on-film (COF) package, and the film is folded in a predetermined direction by 180° and is adhered by a predetermined adhesive material.

There is also provided in accordance with the invention a method of packaging a device. The method includes the steps of (a) mounting a plurality of semiconductor chips on a film, and (b) folding the film in a predetermined direction and packaging the plurality of semiconductor chips in one package.

In one embodiment, before step (a), the method further includes the steps of forming an insulating film and forming a conductive pattern on the surface of the insulating film. The film can be folded two or more times such that at least one semiconductor chip is interposed between surfaces of the film. The film can be folded by 180° and is adhered by an adhesive material.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 is a sectional view of a conventional tape carrier package (TCP);

FIGS. 2 through 4 illustrate a sequence for packaging two semiconductor chips in one package according to an embodiment of the present invention.

FIG. 5 is a side view of a tape carrier package (TCP) which packages two semiconductor chips in one package according to the embodiment of the present invention in FIGS. 2 through 4.

### DETAILED DESCRIPTION OF THE INVENTION

The present invention will be described more fully hereinafter with reference to the accompanying drawings in which preferred embodiments of the invention are shown.

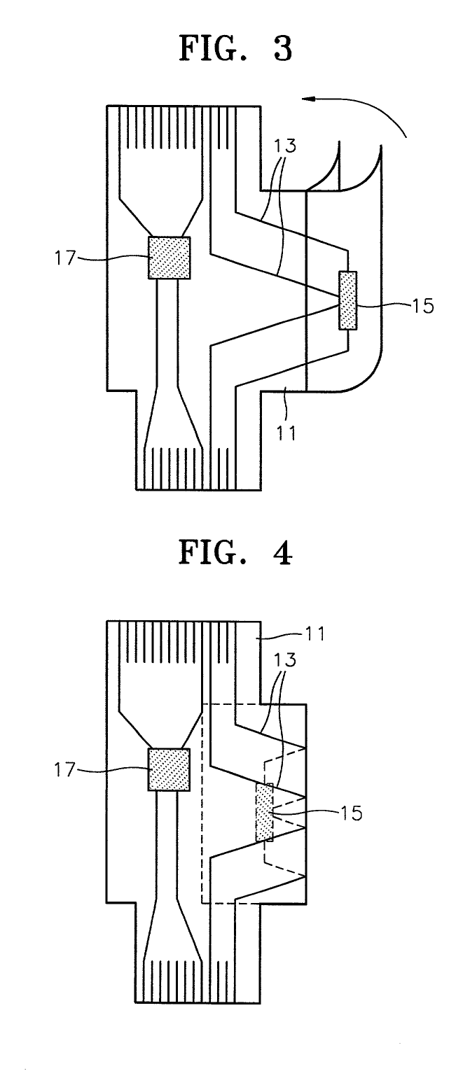

FIGS. 2 through 4 illustrate a sequence for packaging two semiconductor chips in one package according to an embodiment of the present invention. For the convenience of explanation, FIGS. 2 through 4 illustrate a case where two semiconductor chips are packaged in one package, that is, a tape carrier package (TCP). However, the present invention also includes a case where a plurality of semiconductor chips more than two are packaged in one TCP.

The present invention is also applied to a chip-on-film (COF) structure package. The COF structure and manufacturing method thereof is similar to the structure of the TCP and manufacturing method thereof. However, unlike the TCP, an insulating film of the COF does not include a device hole.

That is, the COF includes a conductive pattern formed on the surface of the insulating film, a protective film formed on the surface of the conductive pattern to protect the conductive pattern, and a semiconductor chip electrically connected to the conductive pattern by bumps. The COF is thinner and more flexible than the TCP.

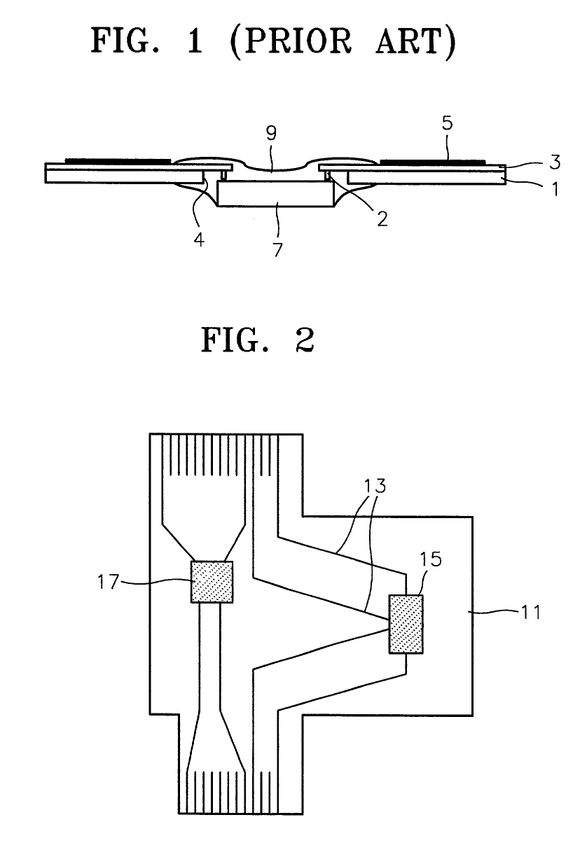

FIG. 2 is a plan view of a film before packaging a tape carrier package (TCP). Referring to FIG. 2, a conductive pattern 13 is formed on the surface of an insulating film 11 for packaging. A protective film is formed on the surface of the conductive pattern 13, and the conductive pattern 13 is electrically connected to electrodes of a first semiconductor chip 15 and a second semiconductor chip 17 by bumps. The structure of the TCP in which each of the semiconductor chips 15 and 17 is mounted, is the same as that of the TCP of FIG. 1. Thus, a detailed description thereof will be omitted.

In FIG. 2, the first semiconductor chip 15 and the second semiconductor chip 17 are mounted on a film (hereinafter, the insulating film and the conductive pattern are referred to as a ‘film’), which is designed such that the two semiconductor chips 15 and 17 are packaged. In general, the semiconductor chip 17 has different functions from those of the first semiconductor chip 15, however, the semiconductor chip 17 may have the same functions as those of the first semiconductor chip 15. In FIG. 3, in order to reduce the size of the TCP, the film on which the two semiconductor chips are mounted is folded in a predetermined direction.

Preferably, a portion of the film on which the semiconductor chips are not mounted is folded toward the insulating film, and can be folded in a direction where the conductive pattern is formed. In general, two or more folds are needed to reduce the size of the package.

FIG. 4 is a plan view of a tape carrier package (TCP) which packages two semiconductor chips 15 and 17 in one package. Referring to FIG. 4, the second semiconductor chip 17 is mounted on the front side of the TCP, and the first semiconductor chip 15 is mounted on the back side of the TCP.

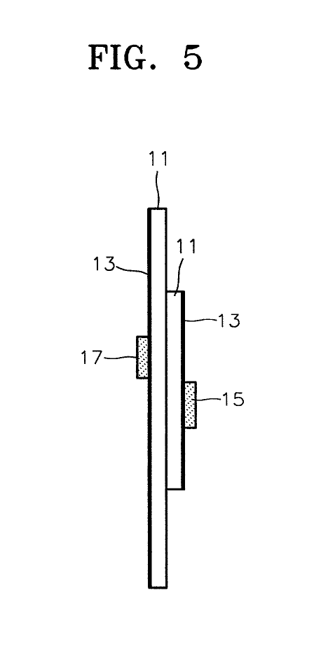

FIG. 5 is a side view of a tape carrier package (TCP) which packages two semiconductor chips in one package according to the preferred embodiment of the present invention. That is, FIG. 5 is a side view of FIG. 4. Referring to FIG. 5, the insulating film 11, which is folded 180°, on which the conductive pattern 13 is formed, is interposed between the first semiconductor chip 15 and the second semiconductor chip 17, thereby mounting the first semiconductor chip 15 and the second semiconductor chip 17. The folded insulating film 11 can be adhered by an adhesive material. Thus, a plurality of semiconductor chips can be packaged in one TCP, thereby reducing the size of the TCP. Further, a module using the TCP can be freely designed.

As described above, the TCP/COF package can mount a plurality of semiconductor chips on one film, and the film can be folded in a predetermined direction and at a predetermined angle and packaged in one package, thereby reducing the size of the package.

Two or more two semiconductor chips can be mounted on one film, and the film can be folded two or more times in a predetermined direction to reduce the size of the TCP or COF package.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A packaging structure for packaging a plurality of semiconductor chips, the packaging structure comprising a film on which the plurality of semiconductor chips are mounted, wherein the film is folded in a predetermined direction so as to package the plurality of semiconductor chips in one package.

2. The packaging structure as claimed in claim 1, wherein the film comprises:
an insulating film; and
a conductive pattern formed on the surface of the insulating film.

3. The packaging structure as claimed in claim 1, wherein the film is folded two or more times such that at least one semiconductor chip is interposed between surfaces of the film.

4. The packaging structure as claimed in claim 1, wherein the package is a tape carrier package (TCP).

5. The packaging structure as claimed in claim 1, wherein the package is a chip-on-film (COF) package.

6. The packaging structure as claimed in claim 1, wherein the film is folded in a predetermined direction by 180° and is adhered by a predetermined adhesive material.

7. A method of packaging a device, comprising:
(a) mounting a plurality of semiconductor chips on a film; and
(b) folding the film in a predetermined direction and packaging the plurality of semiconductor chips in one package.

8. The method as claimed in claim 7, before step (a), further comprising:
forming an insulating film; and
forming a conductive pattern on the surface of the insulating film.

9. The method as claimed in claim 7, wherein the film is folded two or more times such that at least one semiconductor chip is interposed between surfaces of the film.

10. The method as claimed in claim 7, wherein the film is folded by 180° and is adhered by an adhesive material.

11. A package for two semiconductor chips, the package comprising a film on a first side of which the two semiconductor chips are mounted, wherein the film is folded by 180° in the direction of a second side so as to package the two semiconductor chips in one package.

12. The package as claimed in claim 11, wherein the film comprises:
an insulating film; and
a conductive pattern formed on the surface of the insulating film.

13. The package as claimed in claim 11, wherein the film is folded two or more times such that at least one semiconductor chip is interposed between surfaces of the film.

14. The package as claimed in claim 11, wherein the package is a tape carrier package (TCP).

15. The package as claimed in claim 11, wherein the package is a chip-on-film (COF) package.

16. The package as claimed in claim 11, wherein the film is folded in a predetermined direction by 180° and is adhered by a predetermined adhesive material.
